(19) United States
(12) Patent Application Publication
(10) Pub. No.: US 2025/0020994 A1
(43) Pub. Date: Jan. 16, 2025

(54) DUAL POD WITH GUIDE MECHANISM

(71) Applicant: GUDENG PRECISION INDUSTRIAL CO., LTD., NEW TAIPEI (TW)

(72) Inventors: Ming-Chien Chiu, NEW TAIPEI (TW); CHIA-HO CHUANG, NEW TAIPEI (TW); Hsin-Min HSUEH, NEW TAIPEI (TW); Pin-Cheng CHEN, NEW TAIPEI (TW)

(21) Appl. No.: 18/740,956

(22) Filed: Jun. 12, 2024

Related U.S. Application Data
(60) Provisional application No. 63/525,991, filed on Jul. 11, 2023.

(51) Int. Cl. G03F 1/66

(52) U.S. Cl. CPC G03F 1/66

(57) ABSTRACT

The present invention provides a dual pod including an inner pod and an outer pod. The inner pod has at least one engaging portion provided on a relative outside of the inner pod. The outer pod defines an accommodation space for receiving the inner pod. The outer pod has at least one guide mechanism provided on a relative inside of the outer pod, and the guide mechanism is guided by and limited at the engaging portion such that an offset movement of the inner pod within the outer pod is restricted.

### CROSS-REFERENCE TO RELATED APPLICATIONS

This application claims priority to U.S. Provisional Patent Application No. 63/525,991 filed in U.S. on Jul. 11, 2023 the entire contents of which are hereby incorporated by reference.

### BACKGROUND OF THE INVENTION

### Field of the Invention

The present invention relates to a reticle transport pod, particularly to a dual pod, and more particularly to a dual pod with a guide mechanism for an inner pod.

### Description of the Prior Art

In a current extreme ultraviolet (EUV) lithography process, a reticle needs to be protected by an EUV reticle transport pod (EUV POD). Referring to the schematic diagram shown in FIG. 1, the EUV reticle transport pod is a dual pod (1) including an outer pod (10) and an inner pod (20). The reticle is received in the inner pod (20), and the inner pod (20) is received in the outer pod (10). The outer pod (10) primarily has a housing (11) and a door (12), which are joined to define an accommodation space. The inner pod (20) primarily has a lid (21) and a base (22), which are joined to define an accommodation space.

Once the dual pod (1) is closed, a kinematic coupling element (121) provided on an upward-facing surface of the door (12) is joined with and limits the base (22) of the inner pod (20), such that a horizontal movement (that is, along the X axis, the Y axis and the C axis in FIG. 2) of the base (22) is restricted. Multiple pressing components (111) on an inside of the housing (11) press against an upper surface of the lid (21) of the inner pod (20) and apply a downward pressure, such that the lid (21) of the inner pod (20) and the base (22) are fit with each other to limit a vertical movement (that is, along the Z-axis, A-axis and B-axis directions in FIG. 2) of the lid (21), further achieving an object of holding the inner pod (20).

However, the pressing components (111) provide only a one-directional downward pressure in the Z axis, but are unable to limit the lid (21) of the inner pod (20) with respect to the horizontal direction (that is, along the X axis, the Y axis and the C axis indicated by thinner lines in FIG. 2). As such, when the dual pod (1) receives an external force during transportation, the lid (21) of the inner pod (20) makes a horizontal movement relative to the base (22), for example, a movement in the X axis or the Y axis or a deflection about the C axis, in a way that contact areas between the lid (21) and the base (22) rub against each other to produce particles, leading to risks of contamination.

In FIG. 3, when the lid (21) and the base (22) fit with each other, although a limiting member (211) provided on a side of the lid (21) is able to limit the horizontal movement of the lid (21) and the base (22), for example, along the Y axis, for between 0.2 mm and 0.4 mm, the movement to this extent remains unable to prevent occurrence of the particles.

Thus, when the dual pod is closed, there is a need for a solution for suppressing a movement of a lid of an inner pod relative to a base for the related industry.

### SUMMARY OF THE INVENTION

It is an object of the present invention to provide a dual pod, including: an inner pod, having at least one engaging portion provided on a relative outside of the inner pod; and an outer pod, defining an accommodation space for receiving the inner pod, the outer pod having at least one guide mechanism provided on a relative inside of the outer pod, wherein the guide mechanism is guided by and limited at the engaging portion such that an offset movement of the inner pod within the outer pod is restricted.

In a specific embodiment, the guide mechanism has a guiding portion and a connection portion coupled to the guiding portion. The connection portion is connected to an inside of the outer pod, and the guiding portion is away from the inside of the outer pod and abuts against the engaging portion of the inner pod.

In a specific embodiment, the guiding portion is flexible, and the engaging portion is a notch. The guiding portion correspondingly elastically deforms according to a force of abutting against the notch, and is accordingly guided by and limited at the notch.

In a specific embodiment, the guiding portion and the inside of the outer pod have a gap with a stroke distance in between. The gap serves as a tolerance for the guiding portion to flexibly abut against the engaging portion of the inner pod.

In a specific embodiment, the guiding portion includes a first guiding rib and a second guiding rib that are paired. The first guiding rib and the second guiding rib correspondingly elastically deform as an aperture of the notch into which they are placed changes, such that the first guiding rib and the second guiding rib are engaged and limited in the notch.

In a specific embodiment, the notch has a notch edge width, and a width of the guiding portion is less than the notch edge width.

In a specific embodiment, the inner pod includes a base and a lid joined with each other and defining an accommodation space for receiving a reticle; the outer pod includes a door and a housing joined with each other and defining the accommodation space. A vertical direction of the lid is restricted by the guide mechanism and the base, and a horizontal direction of the lid is restriction by the guide mechanism, so as to prevent the inner pod from offsetting or deflecting with respect to an axis by an external force.

In a specific embodiment, the lid has a flange on each of two opposite sides thereof, the engaging portion is located on an outside of the flange, and the guide mechanism corresponds in position to the flange and is guided by and limited at the engaging portion.

In a specific embodiment, the lid has a flange on each of two opposite sides thereof, the engaging portion is located on an outside of the flange, the guide mechanism has a sloped surface for abutting against the flange, and the sloped surface extends from a top portion of the housing toward an inner wall of the housing, such that a vertical direction and at least a horizontal direction of the flange are restricted by the sloped surface.

In a specific embodiment, the sloped surface and an upper surface of the lid define an included angle ranging between 0.01° and 89.9°.

In a specific embodiment, the lid has a flange on each of two opposite sides thereof, the engaging portion is located on an outside of the flange, the guide mechanism has a sloped surface for abutting against the flange, and the sloped surface protrudes upward from an inner top portion of the door, such that a vertical direction and at least a horizontal direction of the flange are restricted by the sloped surface.

In a specific embodiment, the lid has a flange on each of two opposite sides thereof, the engaging portion is located on an outside of the flange, the guide mechanism has at least two guiding ribs arranged in parallel, and the two guiding ribs are formed to protrude upward from an inner top portion of the door, and the two guiding ribs elastically abut against an inside of the engaging portion to achieve the restriction.

### BRIEF DESCRIPTION OF THE DRAWINGS

Reference can be made to the drawings and description below to better understand the present invention. Non-restrictive and non-exhaustive embodiments are described with reference to the drawings below. It shall be noted that the elements in the drawings are not necessarily drawn to their actual sizes, and are depicted to focus on the description of structures and principles.

FIG. 1 is a schematic diagram of a conventional dual pod.

FIG. 2 shows six axes of movements of a conventional lid.

FIG. 3 is a partial structure when a conventional lid fits with a base.

FIG. 4 is a top view of a dual pod of the present invention.

FIG. 5 is a cross-sectional structure taken along the line AA of FIG. 4.

FIG. 6 shows six axes of movements of a lid of the present invention.

FIG. 7 is another partial cross-sectional structure of a dual pod of the present invention.

FIG. 8 is a partial structure of a lid of the present invention.

FIG. 9 is a partial enlarged diagram of FIG. 5.

FIG. 10 is a cross-sectional structure taken along the line BB of FIG. 4.

FIG. 11 is another partial enlarged diagram showing a relationship of the first guiding rib and a second guiding rib with respect to a notch.

FIG. 12A and FIG. 12B are schematic diagrams of contact of a first guiding rib and a second guiding rib with a notch.

FIG. 13 to FIG. 15 are schematic diagrams of a dual pod according to another embodiment of the present invention.

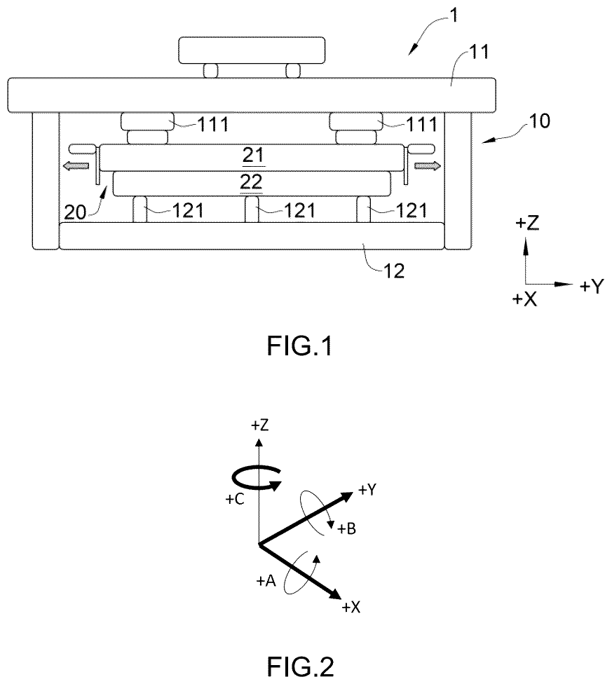

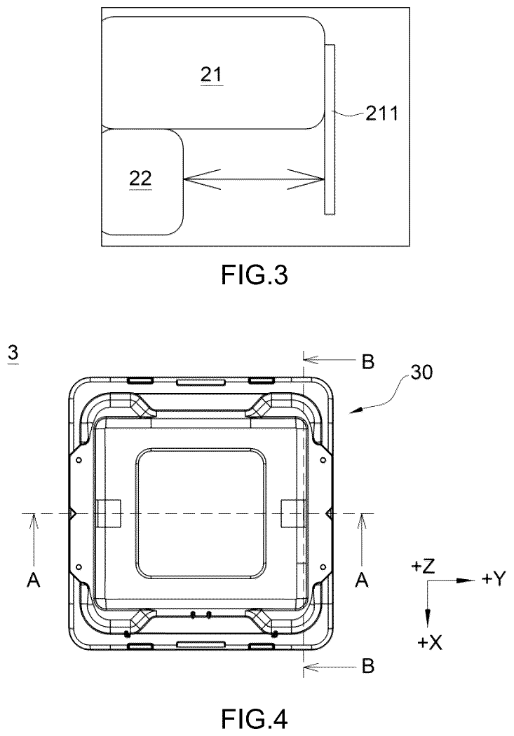

### DETAILED DESCRIPTION OF THE EMBODIMENTS

To better describe the present invention, specific examples and specific embodiments are illustrated with reference to the accompanying drawings below. However, the subject matter of the application may be specifically implemented in various different forms, and the construction covered or claimed by the subject matter of the application is not limited to any exemplary specific embodiments disclosed in the detailed description of the application; it should be understood that the specific embodiments are illustrative of the present invention rather than being restrictive of the present invention. Similarly, the present invention aims at providing a reasonably broad scope for the subject matter applied or covered by the subject matter. Moreover, the accompanying drawings and examples in the present invention are not drawn to scale, and are not intended to correspond to actual relative sizes.

For the purposes of consistency and better understanding, the same features are represented by symbols and numerals in these exemplary accompanying drawings (although not represented as such in some examples). However, the features in different embodiments can be different in other aspects, and such features are not to be narrowly limited to the features shown in the accompanying drawings. The terms such as “first” and “second” in the description and the accompanying drawings are used to differentiate different objects, and are not to be construed as describing any specific order.

FIG. 4 shows a top view of a dual pod (3) of the present invention. FIG. 5 shows a cross-sectional structure taken along the line AA of FIG. 4, wherein the line AA is a central line of the dual pod (3) along the X axis. The dual pod (3) includes an outer pod (30) and an inner pod (40). The outer pod (30) primarily includes a housing (31) and a door (32), and the two are joined to define a space for receiving the inner pod (40). The housing (31) fundamentally has a ceiling (311) and a wall (312) extending downward from the ceiling (311). Each of the housing (31) and the door (32) includes numerous elements. For example, the housing (31) is provided with a pair of handles on an outside, and the door (32) has an operable latch assembly of which details are omitted herein. The elements in the housing (31) and the door (32) can be formed by molding to form a moldable material into specific structures.

The inner pod (40) primarily includes a lid (41) and a base (42), and the two are joined to define a space for receiving a reticle (omitted from the drawing), for example, an EUV reticle. Each of the lid (41) and the base (42) includes numerous elements. For example, the lid (41) is arranged with a gas exchange means and a filtering means on a top portion thereof, and multiple contact portions capable of matching with an inside of the housing (31), and the base (42) has multiple support members provided on an inside thereof for supporting and limiting the reticle.

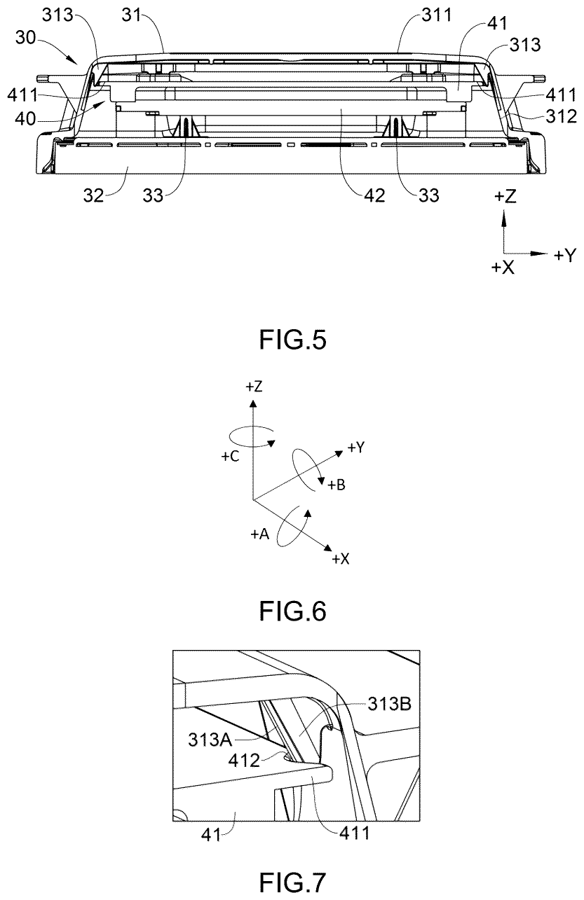

To accommodate the inner pod (40) in the outer pod (30), first of all, the inner pod (40) is placed on the multiple support members (33) provided on the inside of the door (32), for example, kinematic coupling pins generally known, and the housing (31) is placed to cover the door (32). In this case, a hold-down mechanism on the inside of the housing (31) abuts against the corresponding contact portion of the lid (41) of the inner pod (40), such that the Z axis, the B axis and the A axis of the inner pod (40) are restricted, as shown in FIG. 6.

Referring to FIG. 5 showing the cross-sectional structure of the dual pod (3) taken along the line AA of FIG. 4, the housing (31) of the present invention has a pair of guide mechanisms (313) provided on the inside thereof. The guide mechanisms (313) are configured to abut against a flange (that is, a handle 411) of the lid (41) of the inner pod (40) when the housing (31) covers the door (32), so as to limit a horizontal movement and a rotation of the lid (41) between the housing (31) and the door (32), and more particularly such as along the X axis and the Y axis and about the C axis shown in FIG. 6. The present invention does not define the position at which the guide mechanism (313) abuts against the flange. For example, the position can be adjusted according to requirements of the mechanism; the guide mechanism (313) can abut against a center or two ends of the handle (411) in FIG. 13. The guide mechanism (313) is substantially arranged at a meeting point of the ceiling (311) and the inner wall (312), and protrudes from the housing (31) toward the inside. More specifically, a portion of the guide mechanism (313) is connected to the ceiling (311) of the housing (31), and another portion of the guide mechanism (313) is connected to the inner wall (312) of the housing (31).

In this embodiment, the pair of guide mechanisms (313) are located on the inside of the housing (31) corresponding to the line AA. In other possible embodiments, the guide mechanism (313) is arranged on the ceiling (311) or the inner wall (312). The guide mechanism (313) and the housing (31) are respectively formed of different materials, wherein the guide mechanism (313) can be formed of a relatively soft and flexible material with greater elasticity or flexibility, and the material forming the guide mechanism (313) is plastic, rubber, silicone, metal or a combination thereof, so that the guide mechanism (313) can deform under an external force accordingly. The guide mechanism (313) can be a formed as an integral with the housing (31) by molding, or be heterogeneously joined with the housing (31) by buried injection molding.

Further, the guide mechanism (313) is configured to engage with an engaging portion (described below) especially formed on the lid (41) of the inner pod (40) when the housing (31) covers the door (32). With the matching between the engaging portion and the guide mechanism (313), it is even more unlikely that the cover (41) moves horizontally or rotates when affected by an external force received.

FIG. 6 shows directional restrictions on the inner pod (40), and more particularly the lid (41). Compared with FIG. 2 (only the Z axis, the A axis and the B axis are restricted in the conventional arrangement), an effect is brought upon all of the six axes in FIG. 6. The pair of guide mechanisms (313) supplement the restrictions that is absent in FIG. 2, i.e. the X axis, the Y axis and the C axis in FIG. 2, such that almost all directions of the lid (41) are restricted, hence effectively preventing the lid (41) from sliding relative to the base (42). Due to such a structural design, the guide mechanisms (313) can even provide a restriction on the Z-axis direction.

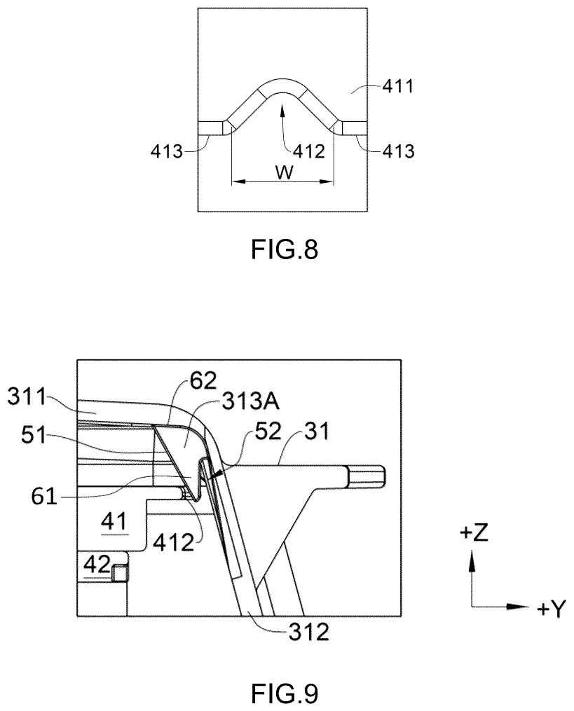

FIG. 7 shows another partial cross-sectional structure of the dual pod (3) of the present invention. FIG. 8 shows a partial structure of the lid (41). FIG. 9 shows a partial enlarged diagram of FIG. 5. The lid (41) of the inner pod (40) of the present invention is configured to have a pair of engaging portions. More specifically, as shown in FIG. 5, the cover (41) has a pair of handles (411), which are provided on two opposite sides and extend outward from the two opposite sides. The handles (411) are designed to match with a lid opening means of a machine. The top view of the lid (41) in FIG. 13 further shows a pair of handles (411), wherein each of the handles (411) has two ends. In this embodiment, the engaging portion is a notch (412) formed on the handle (411), as shown in FIG. 8. The notch (412) has a changing width (aperture), and a maximum width thereof is a notch edge width (W). As shown in FIG. 8, an edge (413) and another edge (413) of the handle (411) appear discontinuously due to the notch (412) defined. In other embodiments, the position of the notch (412) is not limited to being a center of the handle (411).

As shown in FIG. 7, in this embodiment, the guide mechanism (313) has a first guiding rib (313A) and a second guiding rib (313B), and abuts against the handle (411) of the lid (41) by engaging with the notch (412). The first guiding rib (313A) and the second guiding rib (313B) are mutually symmetrical structures. The first guiding rib (313A) and the second guiding rib (313B) are shaped to match with the notch (412), so that the first guiding rib (313A) and the second guiding rib (313B) are able to simultaneously abut against an edge of the notch (412). Moreover, the first guiding rib (313A) and the second guiding rib (313B) correspondingly elastically deform as the width (aperture) of the notch (412) into which they are placed changes, such that the first guiding rib (313A) and the second guiding rib (313B) are engaged and limited in the notch (412).

Referring to FIG. 9, the first guiding rib (313A) has a sloped surface (51), which substantially extends from the ceiling (311) toward the inner wall (312). Thus, when the first guiding rib (313A) is in contact with the edge of the notch (412), the first guiding rib (313A) provides a force in the −Z direction (a direction opposite to the +Z direction) and the −Y direction (a direction opposite to the +Y direction), forcing the lid (41) to move toward the center of the base (42). The sloped surface (51) and an upper surface of the lid (41) define an included angle ranging between 0.01° and 89.9°. Similarly, despite that FIG. 9 does not show the second guiding rib (313B), the second guiding rib (313B) also has the sloped surface (51) consistent with that of the first guiding rib (313A). FIG. 9 further shows that the first guiding rib (313A) of the guide mechanism (313) has a guiding portion (61) and a connection portion (62). The guiding portion (61) is a tooth-like structure, and the connection portion (62) is for connecting to the inside of the housing (31). The guiding portion (61) receives a force when abutting against the notch (412) and correspondingly elastically deforms, allowing the guiding portion (61) to be guided by and limited at the notch (412). Preferably, a mechanical thickness of the guiding portion (61) is smaller so as to exhibit characteristics of elasticity and flexibility, and a mechanical thickness of the connection portion (62) is larger so as to obtain a better mechanical strength. The guiding portion (61) and the inner wall (312) have a gap (52) in between, so that the guiding portion (61) and an inside (that is, the inner wall 312) of the outer pod (30) have a stroke distance (that is, a tolerance) in between, hence providing a buffer in the horizontal direction when the guiding portion (61) deforms. For example, when the guiding portion (61) moves toward the +Y direction in order to limit the lid (41), the gap (52) provides a tolerance. In other possible embodiments, the gap (52) can also be filled with other materials or mechanisms to achieve the same function.

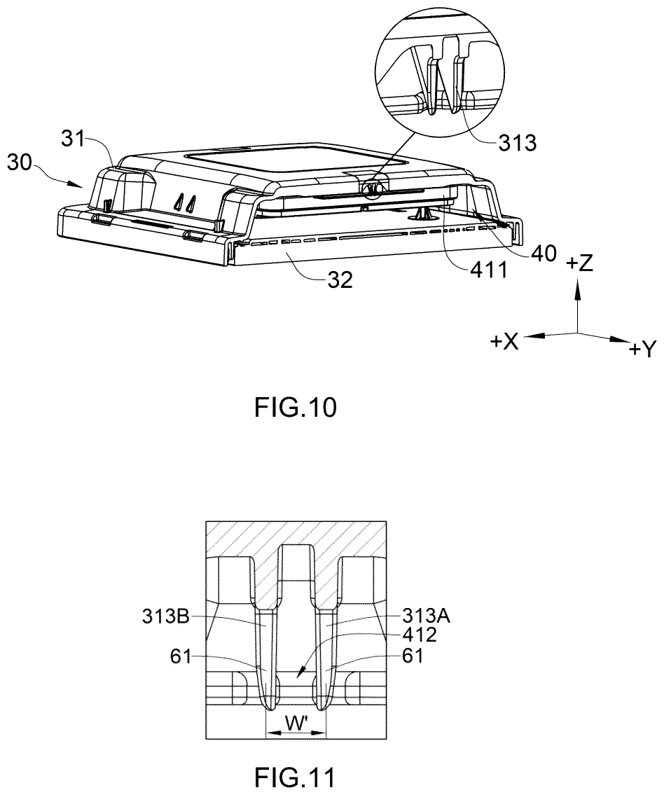

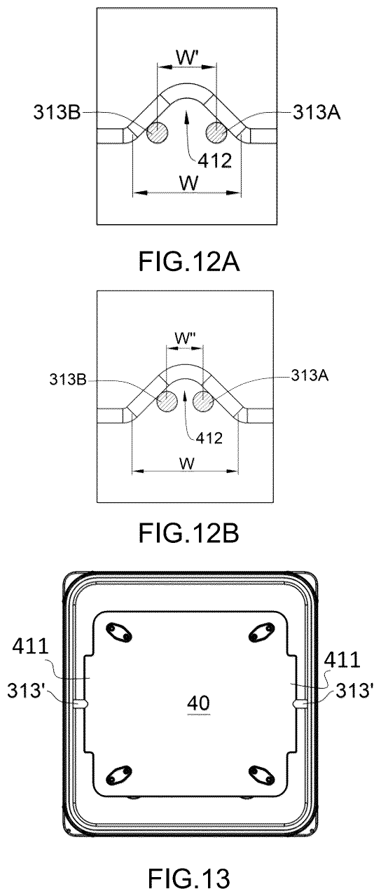

FIG. 10 shows a cross-sectional structure taken along the line BB of FIG. 4, and clearly indicates a relationship between one of the pair of the guide mechanisms (313) and the handle (411). FIG. 11 shows another partial enlarged diagram, and clearly indicates a relationship of the first guiding rib (313A) and the second guiding rib (313B) with respect to the notch (412). FIG. 12A and FIG. 12B show schematic diagrams of contact of the first guiding rib (313A) and the second guiding rib (313B) with the notch (412). When matching of the first guiding rib (313A) and the second guiding rib (313B) with the notch (412) is not implemented, the first guiding rib (313A) and the second guiding rib (313B) have a first guiding width (W′) in between, wherein the first guiding width (W′) is less than the notch edge with (W). When matching of the first guiding rib (313A) and the second guiding rib (313B) with the notch (412) is implemented, the first guiding rib (313A) and the second guiding rib (313B) move toward an end of the notch (412), and the first guiding rib (313A) and the second guiding rib (313B) become close to each other to form a second guiding width (W″), which is less than the first guiding width (W′). The first guiding width (W′) and the second guiding width (W″) are primarily the relationship between the two guiding portions (61), and the connection portion (62) fundamentally has poorer elasticity or flexibility and cannot easily change a width therebetween. When the first guiding rib (313A) and the second guiding rib (313B) are away from the notch (412), the first guiding rib (313A) and the second guiding rib (313B) restore to a predetermined state from a state of being close to each other, that is, the two guiding portions (61) exhibit the first guiding width (W′) in between.

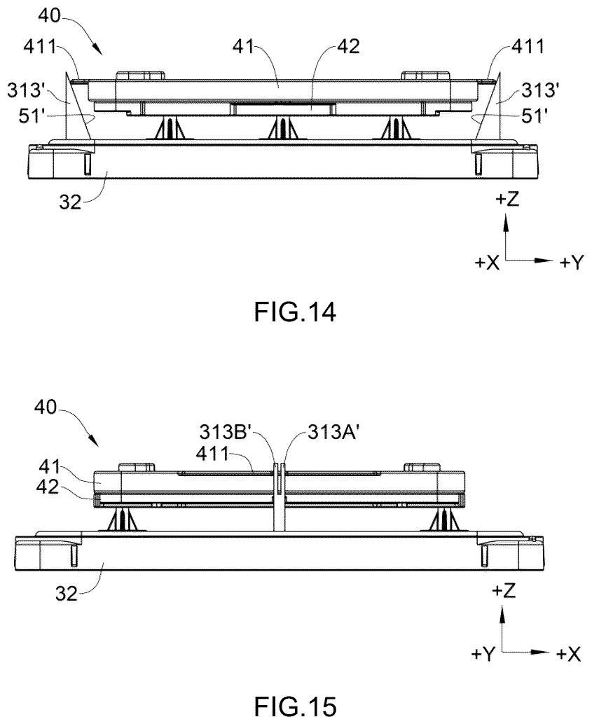

FIG. 13, FIG. 14 and FIG. 15 shows a dual pod according to another embodiment of the present invention, wherein a housing of this embodiment is removed and not depicted. The differences from the embodiment above are that, a pair of guide mechanisms (313′) of this embodiment are disposed on an inner top portion or an upward-facing surface of the door (32), and are configured to protrude upward, such that the guide mechanisms (313′) abut against a flange of the lid (41) of the inner pod (40) when the inner pod (40) is placed on the door (32), thereby restricting a rotation of the lid (41) in the C-axis direction.

In this example, the guide mechanism (313′) similarly has a sloped surface (51′), which extends upward from the inner top portion or the upward-facing surface of the door (32) to readily come into contact with a flange structure of the lid (41), that is, the handle (411). Once an edge of the lid (41) comes into contact with the sloped surface (51′), a force provided by the sloped surface (51′) restricts the lid (41) in the −Z direction (a direction opposite to the +Z direction), the Y-axis direction and the C-axis direction. In this case, the +Z direction of the lid (41) can still be restricted by the hold-down mechanism of the housing (31). Similarly, the handle (411) can be formed to have an engaging portion, for example, the notch (412) above, for matching with the guide mechanism (313′). A guiding portion of the guide mechanism (313′), that is, an end portion, can include a first guiding rib (313A′) and a second guiding rib (313B′), which have an interaction relationship with the notch (412) as that described with reference to FIG. 11 and FIG. 12. The overall structure and shape of the guide mechanism (313′) can be appropriately configured such that a gap is similarly preserved between the first guiding rib (313A′) and the inside of the housing (31) and between the second guiding rib (313B′) and the inside of the housing (31), wherein the gap serves as a buffer space.

In conclusion, the present invention provides a dual pod, including an outer pod having at least a pair of guide mechanisms provided on an inside, wherein a design of the guide mechanisms is especially for abutting against a side or a flange structure of a lid of an inner pod. Thus, during accommodation or transportation of outer pod, a horizontal movement (that is, along the X axis and the Y axis) and a rotation (that is, about the C axis) of the lid can be further suppressed, hence helping in reducing friction between the lid and a base of the inner pod and hence contaminant particles.

However, it should be understood that, the specific embodiments of the present invention are for illustration purposes, and various modifications that may be made without departing from the scope of claims and spirit of the present invention. Moreover, such modifications are encompassed within the scope of the appended claims. Therefore, the specific embodiments provided in the description of the present disclosure are not to be construed as limitations to the present invention, and the essential scope and spirit of the present invention are disclosed in the appended claims.

What is claimed is:

1. A dual pod, comprising:
an inner pod, having at least one engaging portion provided on a relative outside of the inner pod; and
an outer pod, defining an accommodation space for receiving the inner pod, the outer pod having at least one guide mechanism provided on a relative inside of the outer pod, the guide mechanism guided by and limited at the engaging portion such that an offset movement of the inner pod within the outer pod is restricted.

2. The dual pod according to claim 1, wherein the guide mechanism has a guiding portion and a connection portion coupled to the guiding portion, the connection portion is connected to an inside of the outer pod, and the guiding portion is away from the inside of the outer pod and abuts against the engaging portion of the inner pod.

3. The dual pod according to claim 2, wherein the guiding portion is flexible, and the engaging portion is a notch; the guiding portion correspondingly elastically deforms according to a force of abutting against the notch, and is accordingly guided by and limited at the notch.

4. The dual pod according to claim 2, wherein the guiding portion and the inside of the outer pod have a gap with a stroke distance in between, and the gap serves as a tolerance for the guiding portion to flexibly abut against the engaging portion of the inner pod.

5. The dual pod according to claim 3, wherein the guiding portion comprises a first guiding rib and a second guiding rib that are paired, and the first guiding rib and the second guiding rib correspondingly elastically deform as an aperture of the notch into which they are placed changes, such that the first guiding rib and the second guiding rib are engaged and limited in the notch.

6. The dual pod according to claim 3, wherein the notch has a notch edge width, and
a width of the guiding portion is less than the notch edge width.

7. The dual pod according to claim 1, wherein
the inner pod comprises a base and a lid joined with each other and defining an accommodation space for receiving a reticle;
the outer pod comprises a door and a housing joined with each other and defining the accommodation space;
wherein, a vertical direction of the lid is restricted by the guide mechanism and the base, and a horizontal direction of the lid is restricted by the guide mechanism, so as to prevent the inner pod from offsetting and deflecting with respect to an axis by an external force.

8. The dual pod according to claim 7, wherein the lid has a flange on each of two opposite sides thereof, the engaging portion is located on an outside of the flange, and the guide mechanism corresponds in position to the flange and is guided by and limited at the engaging portion.

9. The dual pod according to claim 7, wherein the lid has a flange on each of two opposite sides thereof, the engaging portion is located on an outside of the flange, the guide mechanism has a sloped surface for abutting against the flange, and the sloped surface extends from a top portion of the housing toward an inner wall of the housing, such that a vertical direction and at least a horizontal direction of the flange are restricted by the sloped surface.

10. The dual pod according to claim 9, wherein the sloped surface and an upper surface of the lid define an included angle ranging between 0.01° and 89.9°.

11. The dual pod according to claim 7, wherein the lid has a flange on each of two opposite sides thereof, the engaging portion is located on an outside of the flange, the guide mechanism has a sloped surface for abutting against the flange, and the sloped surface is formed to protrude upward from an inner top portion of the door, such that a vertical direction and at least a horizontal direction of the flange are restricted by the sloped surface.

12. The dual pod according to claim 7, wherein the lid has a flange on each of two opposite sides thereof, the engaging portion is located on an outside of the flange, the guide mechanism has at least two guiding ribs arranged in parallel, and the two guiding ribs are formed to protrude upward from an inner top portion of the door, and the two guiding ribs elastically abut against an inside of the engaging portion to achieve the restriction.
